(19) United States
(12) Patent Application Publication
(10) Pub. No.: US 2025/0194350 A1
(43) Pub. Date: Jun. 12, 2025

(54) DISPLAY DEVICE

(71) Applicant: Japan Display Inc., Tokyo (JP)

(72) Inventors: Hayata AOKI, Tokyo (JP); Jun NITTA, Tokyo (JP); Marina MOCHIZUKI, Tokyo (JP)

(73) Assignee: Japan Display Inc., Tokyo (JP)

(21) Appl. No.: 18/976,390

(22) Filed: Dec. 11, 2024

(30) Foreign Application Priority Data
Dec. 12, 2023 (JP) 2023-209219

(51) Int. Cl. H10K 59/122

(52) U.S. Cl. CPC H10K 59/122

(57) ABSTRACT

According to one embodiment, in a display device, a first pixel includes a first side wall and a first upper layer of a protective layer, a second pixel includes a second side wall and a second upper layer of the protective layer, a third pixel including a third side wall and a third upper layer of the protective layer, the first upper layer, the second upper layer, and the third upper layer have thicknesses equal to each other, the first side wall has a thickness greater than or equal to that of the second side wall, and the thicknesses of the first side wall and the second side wall are greater than the thickness of the third side wall.

### CROSS-REFERENCE TO RELATED APPLICATION

This application is based upon and claims the benefit of priority from Japanese Patent Application No. 2023-209219, filed Dec. 12, 2023, the entire contents of which are incorporated herein by reference.

### FIELD

Embodiments described herein relate generally to a display device.

### BACKGROUND

Organic electroluminescence (organic EL) display devices that emit light by using the energy released when holes injected from the anode recombine with electrons injected from the cathode have been developed.

### BRIEF DESCRIPTION OF THE DRAWINGS

FIG. 1 is a perspective view showing an entire display device according to Embodiment 1.

FIG. 2 is a partial plan view schematically showing a configuration example of the display device.

FIG. 3 is a cross-sectional view of the display device shown in FIG. 2, taken along line A1-A2.

FIG. 4 is a cross-sectional view schematically showing a configuration example of a display device of Embodiment 1.

FIG. 5 is a cross-sectional view schematically showing an example of Embodiment 1.

FIG. 6 is a cross-sectional view illustrating a step in a method of manufacturing the display device of Embodiment 1.

FIG. 7 is a cross-sectional view illustrating a step in the method of manufacturing the display device of Embodiment 1.

FIG. 8 is a cross-sectional view illustrating a step in the method of manufacturing the display device of Embodiment 1.

FIG. 9 is a cross-sectional view illustrating a step in the method of manufacturing the display device of Embodiment 1.

FIG. 10 is a cross-sectional view illustrating a step in the method of manufacturing the display device of Embodiment 1.

FIG. 11 is a cross-sectional view illustrating a step in the method of manufacturing the display device of Embodiment 1.

FIG. 12 is a cross-sectional view illustrating a step in the method of manufacturing the display device of Embodiment 1.

FIG. 13 is a cross-sectional view illustrating a step in the method of manufacturing the display device of Embodiment 1.

FIG. 14 is a cross-sectional view illustrating a step in the method of manufacturing the display device of Embodiment 1.

FIG. 15 is a cross-sectional view illustrating a step in the method of manufacturing the display device of Embodiment 1.

FIG. 16 is a cross-sectional view illustrating a step in the method of manufacturing the display device of Embodiment 1.

FIG. 17 is a cross-sectional view illustrating a step in the method of manufacturing the display device of Embodiment 1.

FIG. 18 is a cross-sectional view illustrating a step in the method of manufacturing the display device of Embodiment 1.

FIG. 19 is a cross-sectional view illustrating a step in the method of manufacturing the display device of Embodiment 1.

FIG. 20 is a cross-sectional view illustrating a step in the method of manufacturing the display device of Embodiment 1.

FIG. 21 is a cross-sectional view illustrating a step in the method of manufacturing the display device of Embodiment 1.

FIG. 22 is a cross-sectional view illustrating a step in the method of manufacturing the display device of Embodiment 1.

FIG. 23 is a cross-sectional view illustrating a step in the method of manufacturing the display device of Embodiment 1.

FIG. 24 is a cross-sectional view illustrating a step in the method of manufacturing the display device of Embodiment 1.

FIG. 25 is a cross-sectional view illustrating a step in a method of manufacturing a display device of Comparative Example 1.

FIG. 26 is a cross-sectional view illustrating a step in the method of manufacturing the display device of Comparative Example 1.

FIG. 27 is a cross-sectional view illustrating a step in the method of manufacturing the display device of Comparative Example 1.

FIG. 28 is a cross-sectional view illustrating a step in a method of manufacturing a display device of Comparative Example 2.

FIG. 29 is a cross-sectional view showing another configuration example of the display device according to Embodiment 1.

FIG. 30 is a cross-sectional view illustrating a step in a method of manufacturing a display device of Configuration Example 1.

FIG. 31 is a cross-sectional view illustrating a step in the method of manufacturing the display device of Configuration Example 1.

FIG. 32 is a cross-sectional view illustrating a step in the method of manufacturing the display device of Configuration Example 1.

FIG. 33 is a cross-sectional view illustrating a step in the method of manufacturing the display device of Configuration Example 1.

FIG. 34 is a cross-sectional view illustrating a step in the method of manufacturing the display device of Configuration Example 1.

FIG. 35 is a cross-sectional view illustrating a step in the method of manufacturing the display device of Configuration Example 1.

FIG. 36 is a cross-sectional view illustrating a step in the method of manufacturing the display device of Configuration Example 1.

### DETAILED DESCRIPTION

In general, according to one embodiment, a display device comprises a plurality of pixels including a first pixel, a second pixel and a third pixel; and a bank provided between each adjacent pair of the plurality of pixels, each of the plurality of pixels comprising, on a base, an anode, an organic EL layer provided on the anode, a protective layer provided to cover a side surface of the organic EL layer, and a cathode provided in an aperture of the protective layer and the bank, so as to be in contact with the organic EL layer, wherein the protective layer comprises a side wall provided on a side surface of the organic EL layer, and an upper layer provided on an upper surface of the organic EL layer, the first pixel includes a first side wall and a first upper layer of the protective layer, the second pixel includes a second side wall and a second upper layer of the protective layer, the third pixel includes a third side wall and a third upper layer of the protective layer, the first upper layer, the second upper layer, and the third upper layer have thicknesses equal to each other, the first side wall has a thickness greater than or equal to that of the second side wall, and the thicknesses of the first side wall and the second side wall are greater than the thickness of the third side wall.

An object of this embodiment is to provide a display device with an improved display quality.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### Embodiment 1

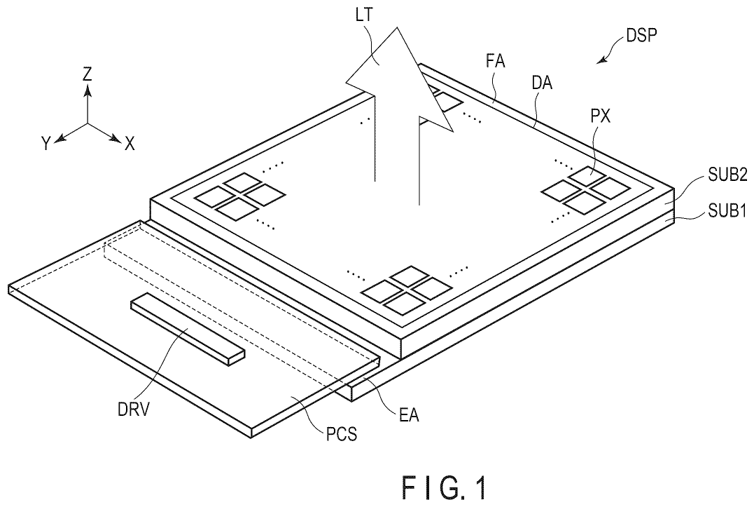

FIG. 1 is a perspective view showing a display device of Embodiment 1 in its entirety. A display device DSP has a display area DA and a peripheral area FA provided to surround the display area DA on a substrate SUB1. The display device DSP includes a plurality of pixels PX arranged in the display area DA. In the display device DSP, light LT is transmitted from a rear surface thereof to a front surface, and vice versa.

The display area DA has an upper surface on which a substrate SUB2 is provided with as a sealing material. The substrate SUB2 is fixed to the substrate SUB1 by sealant (not shown) provided to surround the display area DA. The display area DA formed on the substrate SUB1 is sealed by the substrate SUB2, as the sealing material, and the sealant so as not to be exposed to the atmosphere.

An area EA at an end portion of the substrate SUB1 is located on an outer side the substrate SUB2. In the area EA, a wiring substrate PCS is provided. The wiring substrate PCS is provided with a drive element DRV that outputs video signals and drive signals. The signals from the drive element DRV are input to the pixels PX in the display area DA via the wiring substrate PCS. The pixels PX emit light based on the video signals and various control signals.

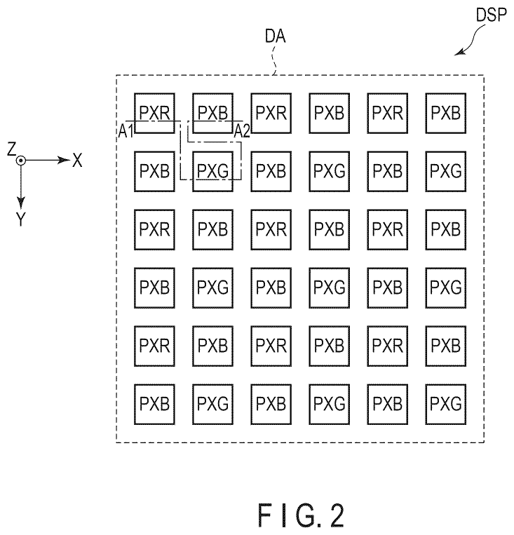

FIG. 2 is a partial plan view schematically showing a configuration example of a display device. The plurality of pixels PX include pixels PXR that emit red light, pixels PXG that emit green light, and pixels PXB that emit blue light. The pixels PXR, pixels PXG, and pixels PXB may as well be referred to as first pixels, second pixels, and third pixels, respectively. Each pixel PXR is arranged adjacent to respective pixels PXB along the first direction X and the second direction Y. Each pixel PXG is arranged adjacent to respective pixels PXB along the first direction X and the second direction Y. Each pixel PXB is arranged adjacent to a respective pixel PXR along the first direction and adjacent to a respective pixel PXG along the second direction Y.

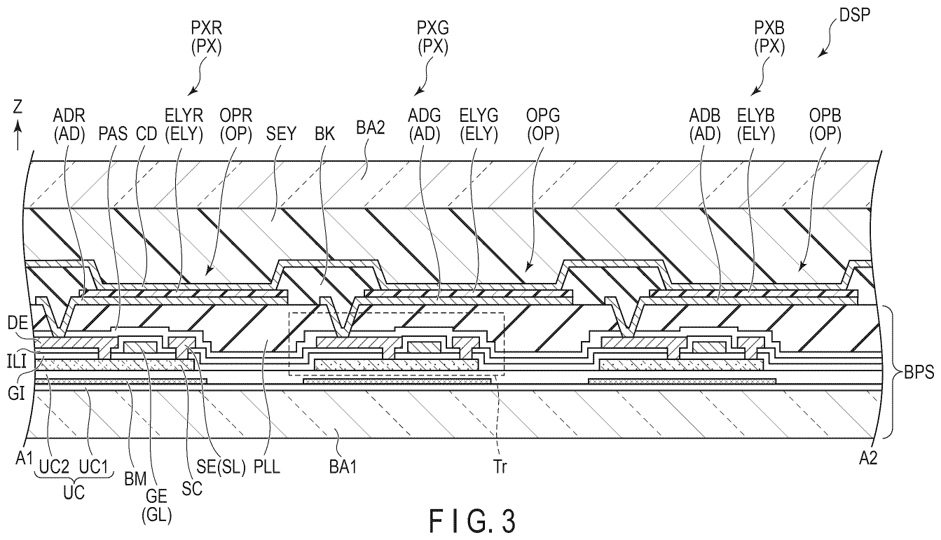

FIG. 3 is a cross-sectional view of the display device shown in FIG. 2 taken along line A1-A2.

A base BAL is made of a material, for example glass or a resin material. As the resin material, for example, acrylic, polyimide, polyethylene terephthalate, polyethylene naphthalate or the like may be used, and it may be formed in a single layer or multiple layers of any of these.

On the base BAL, an insulating layer UC1 is provided. The insulating layer UC1 is formed of a single layer of, for example, silicon oxide film or silicon nitride film or a stacked layer of these.

On the insulating layer UC1, a light shielding layer BM may be provided so as to overlap a transistor Tr. The light shielding layer BM suppresses changes in transistor characteristics due to the entering of light from a rear surface of a channel of the transistor Tr. When the light shielding layer BM is formed from a conductive layer, it is also possible to impart a back gate effect to the transistor Tr by applying a predetermined electric potential.

An insulating layer UC2 is provided to cover the insulating layer UC1 and the light shielding layer BM. For the material of the insulating layer UC2, a material similar to that of the insulating layer UC1 can be used. Note that the insulating layer UC2 may be made of a material different from that of the insulating layer UC1. For example, the insulating layer UC1 may be made of silicon oxide, and the insulating layer UC2 may be made of silicon nitride. The insulating layers UC1 and UC2 are collectively referred to as the insulating layer UC.

On the insulating layer UC, the transistor Tr is provided. The transistor Tr includes a semiconductor layer SC, an insulating layer GI, a gate electrode GE (scanning line), an insulating layer ILI, a source electrode SE (signal line), and a drain electrode DE.

For the semiconductor layer SC, amorphous silicon, polysilicon, or an oxide semiconductor is used.

As the insulating layer GI, a single layer of, for example, silicon oxide or silicon nitride or a stacked layer of these is provided.

For the gate electrode GE, for example, a molybdenum-tungsten alloy (MoW) is used. Note that the gate electrode GE may be formed to be integrated with the respective scanning line GL.

The insulating layer ILI is provided to cover the semiconductor layer SC and the gate electrode GE. The insulating layer ILI is formed from a single layer of, for example, silicon oxide or silicon nitride, or a stacked layer of these.

On the insulating layer ILI, a source electrode SE and a drain electrode DE are provided. The source electrode SE and the drain electrode DE are connected to the source region and the drain region of the semiconductor layer SC, respectively, via contact holes provided in the insulating layer ILI and the insulating layer GI, respectively. The source electrode SE may be formed to be integrated with the respective signal line.

An insulating layer PAS is provided to cover the source electrode SE, the drain electrode DE, and the insulating layer ILI. An insulating layer PLL is provided to cover the insulating layer PAS.

The insulating layer PAS is formed from an inorganic insulating material. The inorganic insulating material may be, for example, a single layer of silicon oxide or silicon nitride or a stacked layer of these. The insulating layer PLL is formed from an organic insulating material. The organic insulating material may be, for example, an organic material such as photosensitive acrylic, polyimide, or the like. With the insulating layer PLL thus provided, steps caused by the transistor Tr can be planarized.

On the insulating layer PLL, an anode AD is provided. The anode AD is connected to the drain electrode DE via respective contact holes provided in the insulating layers PAS and PLL. The anode provided in the pixel PXR is referred to as an anode ADR, the anode provided in the pixel PXB is referred to as an anode ADB, and the anode provided in the pixel PXG is referred to as an anode ADG. When there is no need to distinguish the anode ADR, anode ADG, and anode ADB from each other, they are simply referred to as an anode AD.

The anode AD can be formed, for example, from a stacked body of a reflective electrode and a transparent electrode. The reflective electrode is formed using, for example, a conductive material having a high reflectivity, such as silver (Ag) or aluminum (Al). Apart from this, the reflective electrode RD may as well be formed using an aluminum (Al) alloy. In this case, the reflective electrode RD has a three-layer structure consisting in which a sufficiently thin layer of a barrier metal such as titanium (Ti) is stacked on aluminum (Al) or an aluminum alloy, and further a layer of indium tin oxide (ITO) is stacked on top. Examples of the material that can be alloyed with aluminum include neodymium (Nd), titanium (Ti), tantalum (Ta), and lanthanum (La). The transparent electrode is formed using, for example, indium zinc oxide (IZO) or indium zinc oxide (IZO).

In this embodiment, the configuration from the base BAL to the insulating layer PLL is referred to as a backplane BPS.

Between each adjacent pair of anodes AD, a bank (which may as well be referred to as a protrusion or a rib) is provided. For the material for the bank BK, an organic material similar to that of the insulating layer PLL is used. The bank BK is opened to expose a part of the anode AD.

An aperture in each pixel PXR is referred to as an aperture OPR, an aperture in each pixel PXB is referred to as an aperture OPB, and an aperture in each pixel PXG is referred to as an aperture OPG. When there is no need to distinguish the aperture OPR, aperture OPB, and aperture OPG, they are simply referred to as apertures OP.

An end portion of the aperture OP should preferably be formed into a smooth tapered shape in a cross-sectional view. If the end portion of the aperture OP is formed into a steep shape, a coverage error may occur in the organic EL layer ELY, which is formed later.

The organic EL layer ELY is provided between each adjacent pair of banks BK so as to overlap the respective anode AD. Although the details thereof will be described more later, the organic EL layer ELY includes a hole injection layer HIL, a hole transport layer HTL, an emission layer EML, an electron transport layer ETL, and an electron injection layer EIL. The organic EL layer ELY may as well further include an electron blocking layer, and a hole blocking layer, if necessary.

The organic EL layer provided in the pixel PXR is referred to as an organic EL layer ELYR, the organic EL layer provided in the pixel PXB is referred to as an organic EL layer ELYB, and the organic EL layer provided in the pixel PXG is referred to as an organic EL layer ELYG. When there is no need to distinguish the organic EL layer ELYR, the organic EL layer ELYG, and the organic EL layer ELYB from each other, they are simply referred to as organic EL layers ELY.

On the organic EL layer ELY, a cathode CD is provided. The cathode CD is formed from, for example, a magnesium-silver alloy (MgAg) film, a single layer of silver (Ag) film, or a stacked layer of silver (Ag) and a transparent conductive material, or the like. For the transparent conductive material, for example, indium tin oxide (ITO), indium zinc oxide (IZO) or the like may be used.

An insulating layer SEY is provided to cover the cathode CD. The insulating layer SEY has a function of preventing moisture from penetrating into the organic EL layer ELY from outside. As the insulating layer SEY, a type having a high gas-barrier property is suitable. As the insulating layer SEY, for example, an insulating layer comprising an organic insulating layer interposed between two inorganic insulating layers containing nitrogen can be used. As the material for the organic insulating layer, acrylic resin, epoxy resin, polyimide resin or the like can be used. As the material for the inorganic insulating layer containing nitrogen, for example, silicon nitride or aluminum nitride can be used.

On the insulating layer SEY, a base BA2 is provided. The base BA2 is formed of a material similar to that of the base BAL. Between the base BA2 and the insulating layer SEY, an inorganic insulating layer or an organic insulating layer having light transmissivity may as well be provided. The organic insulating layer may as well have a function of adhering the insulating layer SEY and the base BA2 with each other.

The light emission generated by the organic EL layer ELY is extracted upwards via the cathode CD. In other words, the display device DSP of this embodiment has a top emission structure.

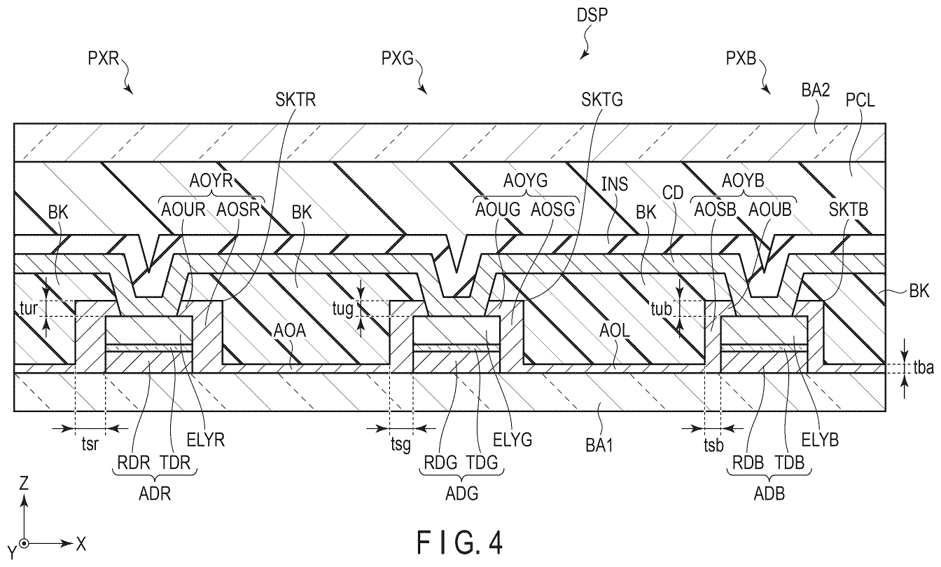

FIG. 4 is a cross-sectional diagram schematically showing an example of the configuration of the display device of Embodiment 1. Note that FIG. 4 only shows the configuration in the vicinity of the organic EL layer ELY in the display device DSP. In FIG. 4, the anodes AD (the anode ADR, anode ADG, anode ADB) are provided on the backplane BPS.

On the anode AD, an organic EL layer ELY is provided. On the anode ADR, an organic EL layer ELYR is provided. On the anode ADB, an organic EL layer ELYB is provided. On the anode ADG, an organic EL layer ELYG is provided.

An upper layer AOUR is provided on the organic EL layer ELYR. A sidewall AOSR is provided to cover side surfaces of the anode ADR, the organic EL layer ELYR, and the upper layer AOUR. The upper layer AOUR and the side wall AOSR are formed to be integrated as one body. The layer formed integrally is referred to as a sacrificial layer AOYR. The thickness of the upper layer AOUR and the thickness of the side wall AOSR are referred to as a thickness tur and a thickness tsr, respectively. The anode ADR, the organic EL layer ELYR, and the sacrificial layer AOYR are collectively referred to as a stacked body SKTR.

An upper layer AOUG is provided on the organic EL layer ELYG. A side wall AOSG is provided to cover side surfaces of the anode ADG, the organic EL layer ELYG, and the upper layer AOUG. The upper layer AOUG and the side wall AOSG are formed to be integrated as one body. The layer formed integrally is referred to as a sacrificial layer AOYG. The thickness of the upper layer AOUG and the thickness of the side wall AOSG are referred to as a thickness tug and a thickness tsg, respectively. The anode ADG, the organic EL layer ELYG, and the sacrificial layer AOYG are collectively referred to as a stacked body SKTG.

An upper layer AOUB is provided on the organic EL layer ELYB. A side wall AOSB is provided to cover side surfaces of the anode ADB, the organic EL layer ELYB, and the upper layer AOUB. The upper layer AOUB and the side wall AOSB are formed to be integrated as one body. The layer formed integrally is referred to as a sacrificial layer AOYB. The thickness of the upper layer AOUB and the thickness of the side wall AOSB are referred to as a thickness tub and a thickness tsb, respectively. The anode ADB, the organic EL layer ELYB, and the sacrificial layer AOYB are collectively referred to as a stacked body SKTB.

The thickness tur, thickness tug, and thickness tub should be equal to each other (tur=tug=tub). The thickness tsr, thickness tsg, and thickness sb are less in this order (tsr>tsg>tsb). But note the thickness tsr and thickness tsg may be the same (tsr=tsg). In other words, the thickness tsr is greater than or equal to the thickness tsg, and the thickness tsr and thickness tsg are greater than the thickness tsb (tsr≥tsg>tsb).

Between each adjacent pair of the sacrificial layer AOYR, sacrificial layer AOYG, and sacrificial layer AOYB, there is an area AOA formed from the same material as that of these sacrificial layers and disposed on the base BAL. Note that the sacrificial layer AOYR, sacrificial layer AOYG, and sacrificial layer AOYB, and the area AOA are formed to be integrated as one body to constitute a protective layer AOL.

The thickness of the area AOA is referred to as a thickness tba. Here, the thickness tba is less than the thickness tur, thickness tug, and thickness tub (tur=tug=tub>tba).

On the protective layer AOL and between each adjacent pair of organic EL layers ELY, a bank BK is provided. A cathode CD is provided to cover the bank BK, the stacked body SKTR, the stacked body SKTG, and the stacked body SKTB.

An insulating layer INS and an insulating layer PCL are formed to cover the cathode CD. On the insulating layer PCL, a base BA2 is provided.

The upper layer AOUR, the side wall AOSR, the upper layer AOUG, the side wall AOSG, the upper layer AOUB, the side wall AOSB, and the area AOA are formed, for example, of aluminum oxide (AlOx). In other words, the protective layer AOL is formed, for example, of aluminum oxide (AlOx). The materials of the insulating layer INS, the insulating layer PCL, and the base BA2 will be described later.

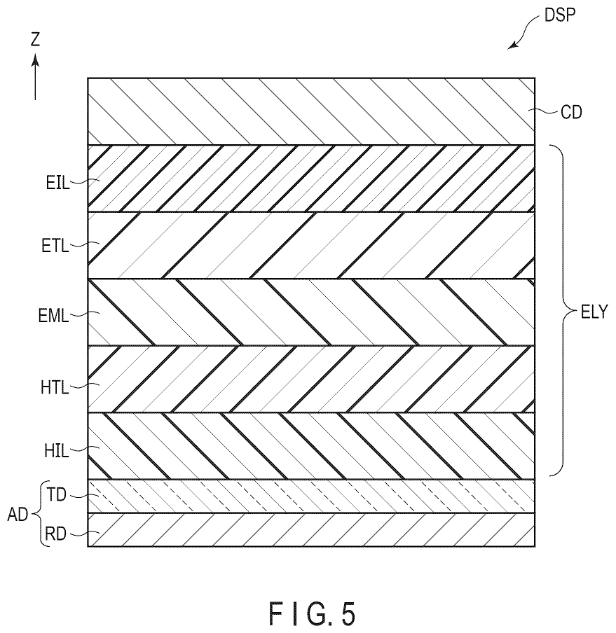

FIG. 5 is a cross-sectional view schematically showing an example of the configuration of Embodiment 1. FIG. 5 is a partial enlarged view of FIG. 4. As shown in FIG. 5, an organic EL layer ELY is provided between the anode AD and the cathode CD along the third direction Z. The organic EL layer ELY includes a hole injection layer HIL, a hole transport layer HTL, an emission layer EML, an electron transport layer ETL, and an electron injection layer EIL, which are stacked one on another along the third direction Z.

In the display device DSP of this embodiment, the anode AD, the organic EL layer ELY, and the cathode CD are stacked in this order along the third direction Z. In the organic EL layer ELY, the hole injection layer HIL, the hole transport layer HTL, the emission layer EML, the electron transport layer ETL, and the electron injection layer EIL are stacked in this order along the third direction Z. Note that the configuration of the embodiment is not limited to this. In the display device DSP of this embodiment, the layers may be stacked in the order of a cathode CD, an organic EL layer ELY, and an anode AD. Further, in the organic EL layer ELY, the layers may be stacked in the order of an electron injection layer EIL, an electron transport layer ETL, an emission layer EML, a hole transport layer HTL, and a hole injection layer HIL.

Although not shown in FIG. 5, a light extraction layer and a sealing layer may be provided on the cathode CD. For example, the insulating layer SEY shown in FIG. 3 can function as a sealing layer.

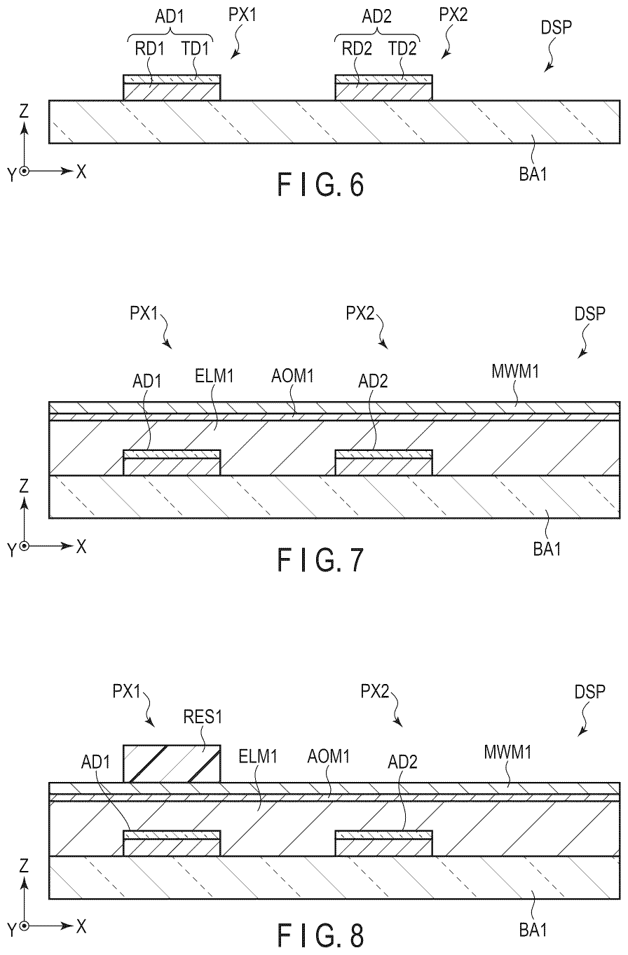

FIGS. 6 to 24 are each a cross-sectional view showing a respective step in a method of manufacturing the display device of Embodiment 1. In FIGS. 6 to 24, the first pixel, which is one of the pixel PXR, pixel PXG, and pixel PXB, is represented as a pixel PX1, and the second pixel, which is another one, is represented as a pixel PX2. In FIGS. 6 to 24, the first pixel (pixel PX1) and the second pixel (pixel PX2) are formed in this order. Although not shown in the figures, the third pixel (which is referred to as a pixel PX3), which is the other one of the pixel PXR, pixel PXG, and pixel PXB, is formed in a manner similar to those of the first and second pixels.

First, the anode AD1 and the anode AD2 are formed on the base BAL (see FIG. 6). The anode AD1 is the anode of the pixel PX1, and the anode AD2 is the anode of the pixel PX2. The anode AD1 includes a reflective electrode RD1 and a transparent electrode TD1. The anode AD2 includes a reflective electrode RD2 and a transparent electrode TD2. Note that FIG. 6 shows the base BAL only, but this is representative of the backplane BPS.

The organic EL layer ELM1, the sacrificial layer AOM1, and the sacrificial layer MWM1 are formed to cover the base BAL, the anode AD1 and anode AD2 (see FIG. 7). The organic EL layer ELM1 is an organic EL layer corresponding to the pixel PX1. Note here that the organic EL layer ELY is assumed to include a hole injection layer HIL, a hole transport layer HTL, an emission layer EML, and an electron transport layer ETL among the hole injection layer HIL, the hole transport layer HTL, the emission layer EML, electron transport layer ETL, and the electron injection layer EIL shown in FIG. 5.

The sacrificial layer AOM1 is formed, for example, of aluminum oxide (AlOx). Aluminum oxide can be formed by atomic layer deposition (ALD).

The sacrificial layer MWM1 is formed, for example, of molybdenum tungsten (MoW). Molybdenum tungsten is formed by the sputtering method.

A resist mask RES1 is formed on the sacrificial layer MWM1 so as to oppose the anode AD1 (see FIG. 8). Note that no resist mask is formed on the anode AD2.

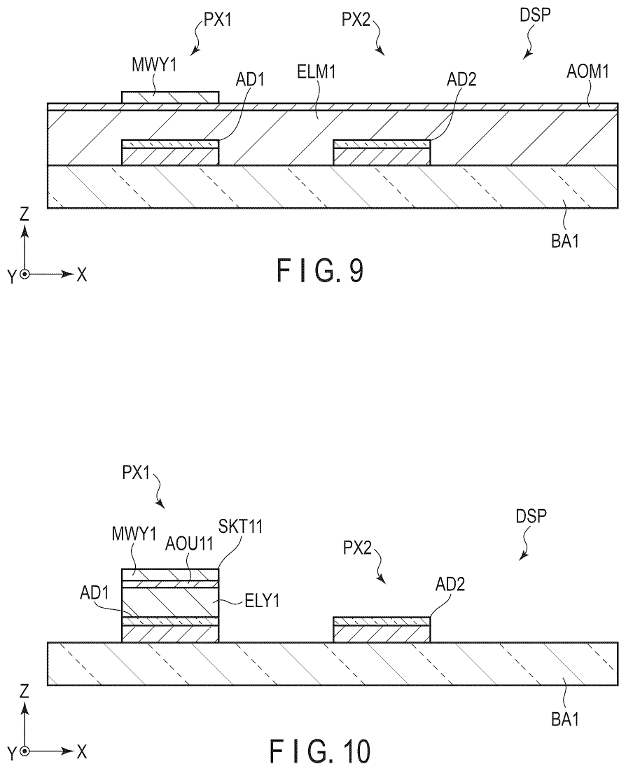

Using the resist mask RES1, the sacrificial layer MWM1 is partially removed by etching. With this processing, a sacrificial layer MWY1 is formed into an island-like shape so as to oppose the anode AD1 and interpose the organic EL layer ELM1 and the sacrificial layer AOM1 therebetween (see FIG. 9).

Using the island-shaped sacrificial layer MWY1 as a mask, the sacrificial layer AOM1 and the organic EL layer ELM1 are partially removed by etching. With this processing, the organic EL layer ELY1 and the upper layer are formed into an island-like shape between the anode AD1 and the sacrificial layer MWY1 (see FIG. 10). The organic EL layer ELM1 and the sacrificial layer AOM1 on the anode AD2 are removed.

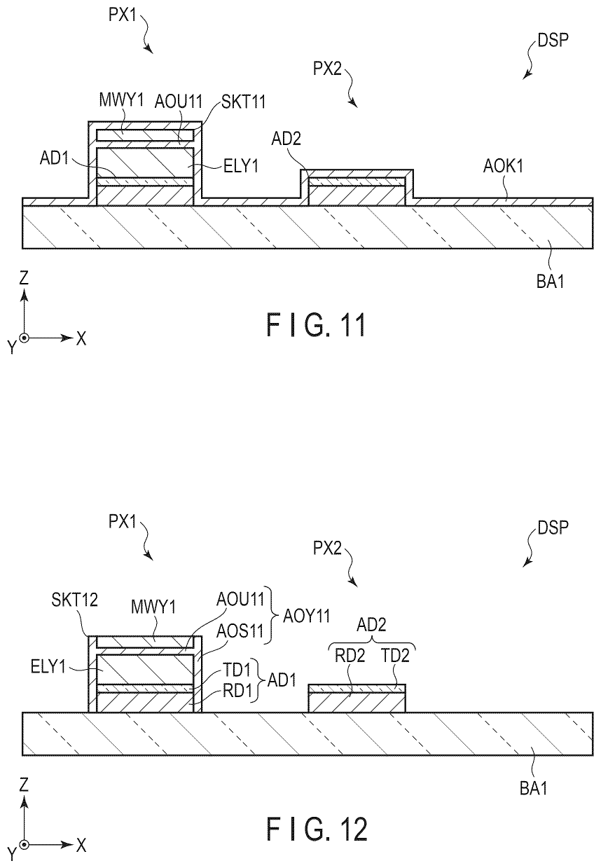

A sacrificial layer AOK1 is formed so as to cover the stacked body SKT11 of the anode AD1, the organic EL layer ELY1, the upper layer AOU11, and the sacrificial layer MWY1, as well as the anode AD2 (see FIG. 11). The sacrificial layer AOK1 is formed from the same material as that of the sacrificial layer AOM1. The upper layer AOU11 and the sacrificial layer AOK1 are integrated with each other as one body.

The sacrificial layer AOK1 is subjected to anisotropic etching, and thus only the area that is in contact with the side surface of the stacked body SKT11 is left and the other areas are removed. A side wall AOS11 is formed from the sacrificial layer AOK1 (see FIG. 12). The upper layer AOU11 and the side wall AOS11 are integrated together to form a sacrificial layer AOY11. The stacked body SKT11 and the sidewall AOS11 are collectively referred to as the stacked body SKT12.

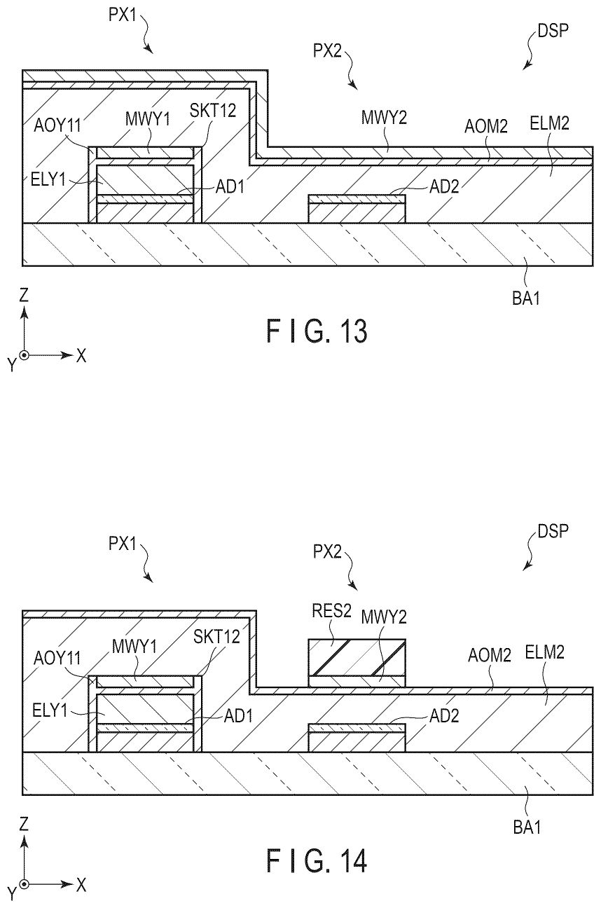

The organic EL layer ELM2, the sacrificial layer AOM2, and the sacrificial layer MWM2 are formed to cover the base BAL, the stacked body SKT12, and the anode AD2 (see FIG. 13). The organic EL layer ELM2 is an organic EL layer corresponding to the pixel PX2. Note here that the organic EL layer ELM2, as well as the organic EL layer ELM1, includes a hole injection layer HIL, a hole transport layer HTL, an emission layer EML, and an electron transport layer ETL among the hole injection layer HIL, the hole transport layer HTL, the emission layer EML, the electron transport layer ETL, and the electron injection layer EIL shown in FIG. 5. The sacrificial layer AOM2 is made of a material similar to that of the sacrificial layer AOM1. A resist mask RES2 is formed on the sacrificial layer MWM2 so as to oppose the anode AD2. Using the resist mask RES2, the sacrificial layer MWM2 is partially removed by etching. With this processing, a sacrificial layer MWY2 is formed into an island-like shape so as to oppose the anode AD2 and interpose the organic EL layer ELM2 and the sacrificial layer AOM2 therebetween (see FIG. 14).

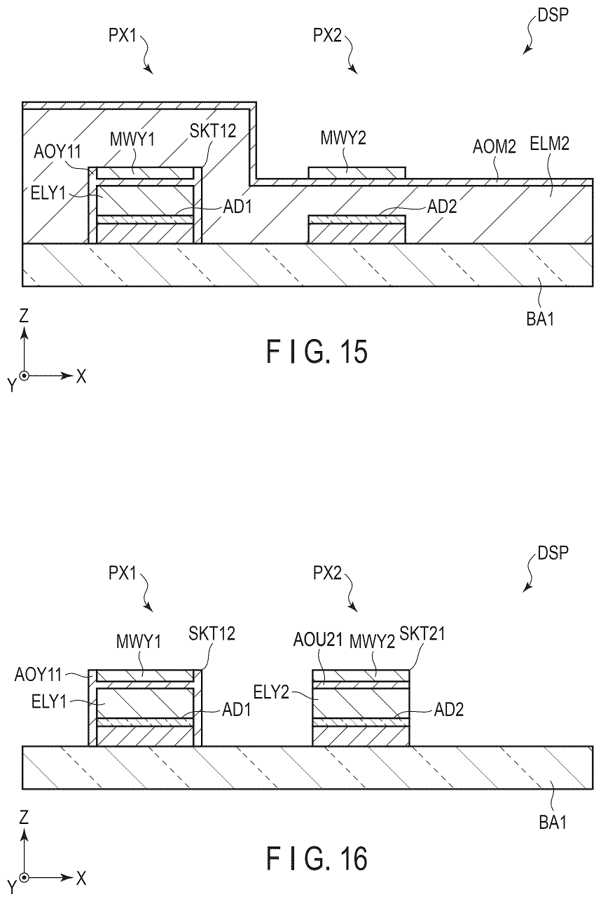

Next, the resist mask RES2 on the sacrificial layer MWY2 is removed (see FIG. 15).

Using the island-shaped sacrificial layer MWY2 as a mask, the organic EL layer ELM2 and the sacrificial layer AOM2 are partially removed by etching. With this processing, the organic EL layer ELY2 and the upper layer AOU2 are formed into an island-like shape between the anode AD2 and the sacrificial layer MWY2 (see FIG. 16). The anode AD2, the organic EL layer ELY2, the upper layer AOU21, and the sacrificial layer MWY2 are collectively referred to as a stacked body SKT21.

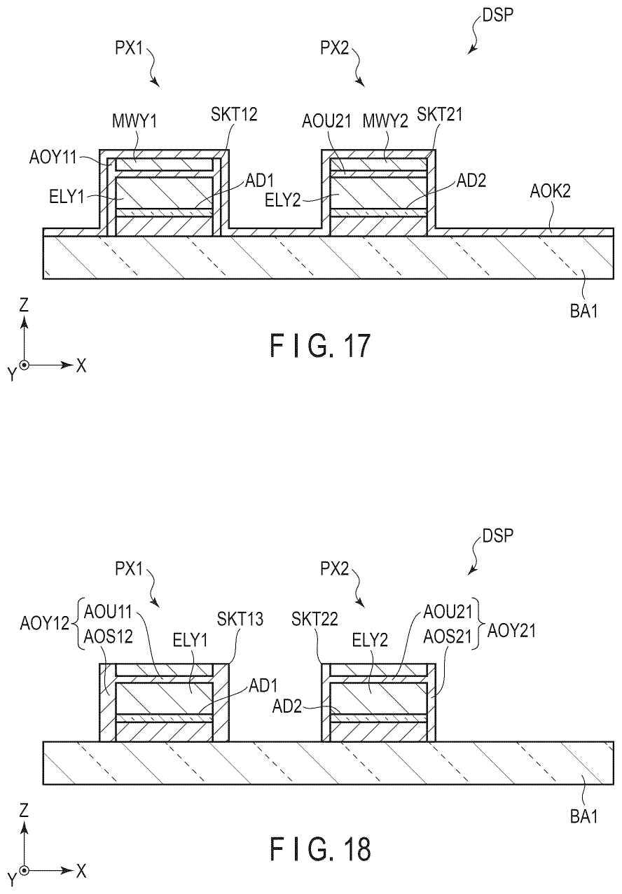

The sacrificial layer AOK2 is formed to cover the stacked body SKT12 and the stacked body SKT21 (see FIG. 17). The sacrificial layer AOK2 is formed of the same material as that of the sacrificial layer AOM1. In FIG. 17, in order to make the drawing easier to understand, the sacrificial layer AOY11 (the upper layer AOU11 and side wall AOS11), the sacrificial layer AOK2, the upper layer AOU21 and the sacrificial layer AOK2 are shown as separate layers, but these are integrated into one body.

The sacrificial layer AOK2 is then subjected to anisotropic etching and thus only the area in contact with a side surface of the stacked body SKT12 and a side surface of the stacked body SKT21 is left to remain, and the other areas are removed. With this processing, a side wall AOS12 is formed from the sacrificial layer AOK2 on the side surface of the stacked body SKT12. Further, a side wall AOS21 is formed on the side surface of the stacked body SKT21 from the sacrificial layer AOK2 (see FIG. 18). As described above, the sacrificial layer AOY11 and sacrificial layer AOK2, as well as the upper layer AOU21 and sacrificial layer AOK2, are integrated with each other into one body, respectively. The side wall AOS12 is an integrated structure of the side wall AOS11 and the sacrificial layer AOK2. The upper layer AOU11 and the side wall AOS12 are integrated with each other to form the sacrificial layer AOY12. The upper layer AOU21 and the side wall AOS21 are integrated into one body and together form the sacrificial layer AOY21. The stacked body SKT12 and the side wall AOS12 are collectively referred to as a stacked body SKT13. The stacked body SKT21 and the side wall AOS21 are collectively referred to as a stacked body SKT22.

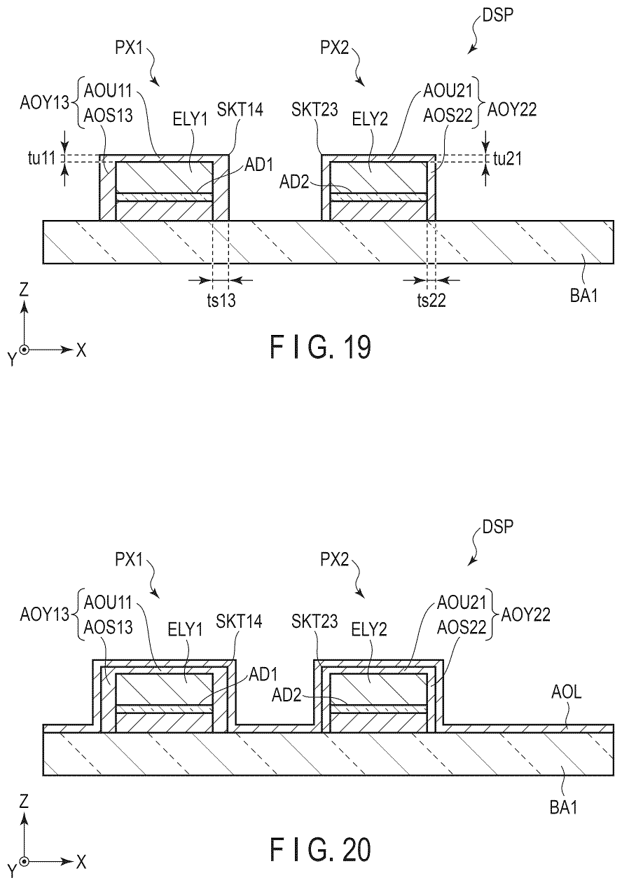

The sacrificial layer MWY1 of the stacked body SKT13 and the sacrificial layer MWY2 of the stacked body SKT22 are removed by etching. At this time, the upper portions of the side wall AOS12 and side wall AOS21 are etched as well at the same time. In this manner, a stacked body SKT14 and a stacked body SKT23 having planarized upper surfaces are obtained from the stacked body SKT13 and stacked body SKT22, respectively (see FIG. 19).

The side wall AOS12 and side wall AOS21 with the etched upper surfaces are referred to as a side wall AOS13 and a side wall AOS22, respectively. The upper layer AOU11 and the side wall AOS13 are collectively referred to as a sacrificial layer AOY13. The upper layer AOU21 and the side wall AOS22 are collectively referred to as a sacrificial layer AOY22.

The thickness of the upper layer AOU11 is defined as a thickness tu11. The thickness of the side wall AOS13 is defined as a thickness ts13. The thickness of the upper layer AOU21 is defined as a thickness tu21. The thickness of the side wall AOS22 is defined as a thickness ts22. The thickness tu11 and the thickness tu21 are the same as each other (tu11=tu21). The thickness ts13 is greater than the thickness 22 (ts13>ts22).

A protective layer AOL is formed to cover the stacked body SKT14 and the stacked body SKT23. The protective layer AOL is formed of the same material as that of the sacrificial layer AOM1 and the sacrificial layer AOM2 (see FIG. 20).

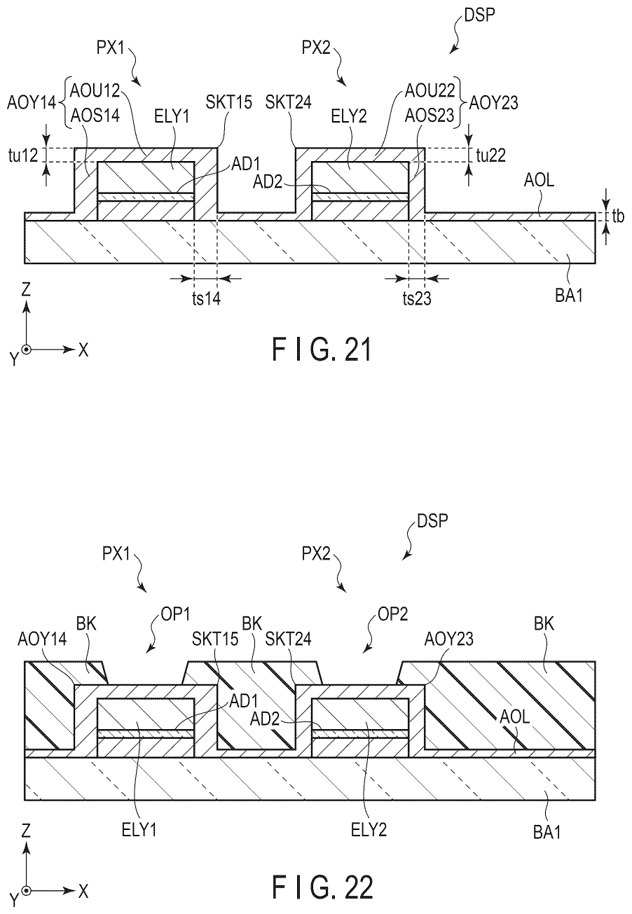

In FIG. 20, in order to make the drawing easier to understand, the sacrificial layer AOY13 (the upper layer AOU11 and side wall AOS13) and the protective layer AOL, as well as the sacrificial layer AOY22 (the upper layer AOU21 and side wall AOS22) and the protective layer AOL are illustrated as separate layers, but these are integrated as one body (see FIG. 21).

As shown in FIG. 21, the upper layer AOU11 and the protective layer AOL are integrated into one body to form the upper layer AOU12. The side wall AOS13 and the protective layer AOL are integrated into one body to form the side wall AOS14. The upper layer AOU12 and the side wall AOS14 are integrated into one body to form the sacrificial layer AOY14. The sacrificial layer AOY14 constitutes a part of the protective layer AOL. The stacked body SKT14 and the sacrificial layer AOY14 are collectively referred to as a stacked body SKT15.

The upper layer AOU21 and the protective layer AOL are integrated into one body to form the upper layer AOU22. The side wall AOS22 and the protective layer AOL are integrated into one body to form the side wall AOS23. The upper layer AOU22 and the side wall AOS23 are integrated into one body to form the sacrificial layer AOY23. The sacrificial layer AOY23 constitutes a part of the protective layer AOL. The stacked body SKT23 and the sacrificial layer AOY23 are collectively referred to as a stacked body SKT24.

The thickness of the upper layer AOU12 is defined as a thickness tu12. The thickness of the side wall AOS14 is defined as a thickness ts14. The thickness of the upper layer AOU22 is defined as a thickness tu22. The thickness of the side wall AOS23 is defined as a thickness ts23. The thickness tu12 and the thickness tu22 are the same as each other (tu12=tu22). Thickness ts14 is greater than the thickness 23 (ts14>ts23).

The thickness tu12 and thickness tu22 are greater than the thickness tu11 and thickness tu21, respectively (tu12=tu22>tu11=tu21). The thickness ts14 is greater than the thickness ts13 (ts14>ts13). The thickness ts23 is greater than the thickness ts22 (ts23>ts22). The thickness ts13 and thickness ts22 may be the same as or different from each other.

A bank BK is formed so as to be in contact with the protective layer AOL between the stacked body SKT15 and the stacked body SKT24, in other words, between the organic EL layer ELY1 and the organic EL layer ELY2. The bank BK is not formed above each of the organic EL layer ELY1 and the organic EL layer ELY2. In other words, above the organic EL layer ELY1 and the organic EL layer ELY2, an aperture OP1 and an aperture OP2 are provided, respectively (see FIG. 22).

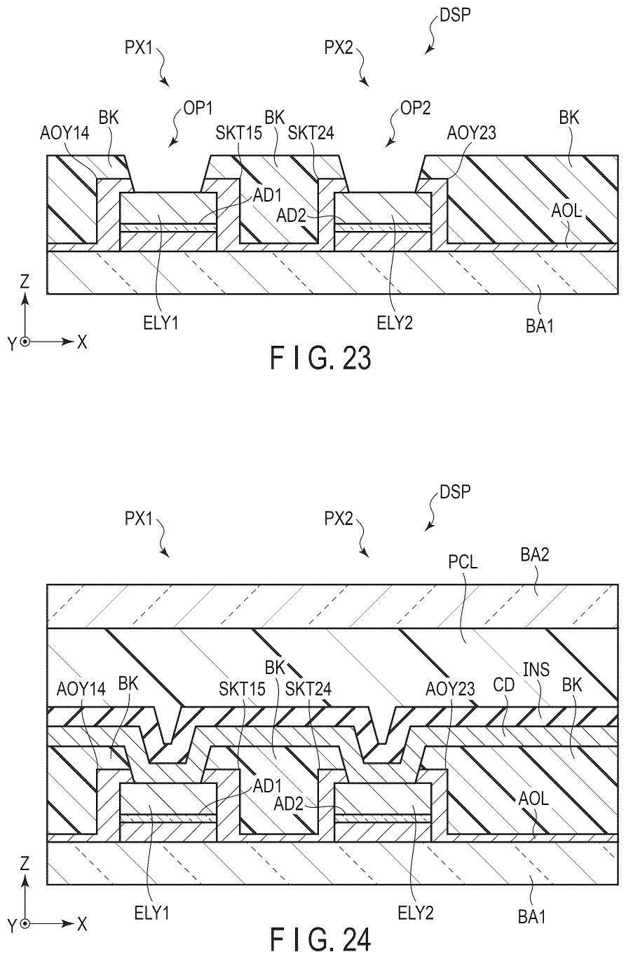

The upper layer AOU12 in the aperture OP1 is removed by etching. Similarly, the upper layer AOU22 in the aperture OP2 is removed by etching. Thus, the organic EL layer ELY1 and the organic EL layer ELY2 are exposed in the aperture OP1 and the aperture OP2 (see FIG. 23).

The cathode CD, the insulating layer INS, and the insulating layer PCL are formed to cover the exposed organic EL layer ELY1 and organic EL layer ELY2, and the bank BK. The base BA2 is provided on the insulating layer PCL (see FIG. 24). Note that though not illustrated in the figure, an electron injection layer EIL may be formed to be in contact with the cathode CD.

In the aperture OP1 and the aperture OP2, the cathode CD is provided on the organic EL layer ELY1 and organic EL layer ELY2, respectively. As described above, the display device DSP of Embodiment 1 is formed.

The insulating layer INS is formed, for example, of silicon nitride (SiN). The insulating layer INS prevents moisture from entering the organic EL layer from the outside. The insulating layer PCL is formed, for example, from a resin insulating material. The insulating layer PCL has a function of planarizing the surface. For the base BA2, a material similar to that of the base BAL can be used.

In order to form the anode and the organic EL layer of the pixel PX3, which is the third pixel, an organic EL layer corresponding to the pixel PX3, a sacrificial layer of a material similar to that of the sacrificial layer AOM1, that is, for example, an aluminum oxide (ALOx), and a sacrificial layer of a material similar to that of the sacrificial layer MWM1, that is, for example, magnesium tungsten (MoW), should be formed so as to cover the anode of the pixel PX3 as in a similar manner shown in FIG. 13, after the process shown in FIG. 18 is completed. As in the case shown in FIG. 8, the side walls should be respectively formed from the two sacrificial layers in the pixel PX3 as well. After that, the process can proceed to that shown in FIG. 19.

As the side wall of the pixel PX3 is formed, side walls are further formed in the pixel PX1 and the pixel PX2, respectively. That is, in the pixel PX1, a side wall is formed to be in contact with side wall AOS12, using a material similar to that of the sacrificial layer AOM1.

In the pixel PX2, a side wall is formed to be in contact with side wall AOS21, using a material similar to that of the sacrificial layer AOM1.

In this embodiment, the pixel PX1, pixel PX2, and pixel PX3 should only be pixel PXR, pixel PXG, and pixel PXB, respectively.

Note that the thickness of the sacrificial layer AOK1 shown in FIG. 11 and the thickness of the sacrificial layer AOK2 shown in FIG. 17 may be changed in accordance with the pixel PX1 and pixel PX2. For example, the thickness of the sacrificial layer AOK1 may be greater than the thickness of the sacrificial layer AOK2. In the pixel PX3 as well, the thickness of the sacrificial layer corresponding to the sacrificial layer AOK1 may as well be different from those of the other pixels.

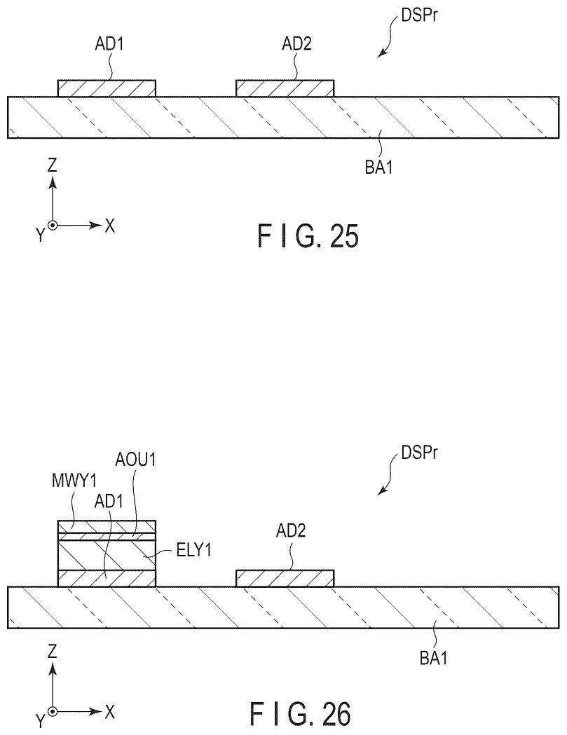

FIGS. 25 to 27 are each a cross-sectional diagram showing a respective step in a method of manufacturing a display device of Comparative Example 1. In the manufacture of a display device DSPr of Comparative Example 1, first, an anode AD1 and an anode AD2 are formed on the base BAL (see FIG. 25). It is assumed here that the anode AD1 and the anode AD2 in the comparative example 1 are transparent electrodes formed of a metal oxide. Example of such a metal oxide include indium tin oxide and indium zinc oxide mentioned above. The processing step shown in FIG. 25 corresponds to that shown in FIG. 6.

Through the processing steps shown in FIGS. 7 to 9, the organic EL layer ELY1, the upper layer AOU1 of the sacrificial layer, and the sacrificial layer MWY1 are formed on the anode AD1. On the anode AD2, the sacrificial layer has been removed (see FIG. 26). The processing step shown in FIG. 22 corresponds to that shown in FIG. 10.

Next, a side wall AOS1 is formed so as to be in contact with side surfaces of the anode AD1, the organic EL layer ELY1, the upper layer AOU1, and the sacrificial layer MWY1. First, here, a material film, which gives rise to the side wall AOS1, is formed to cover the stacked body of the organic EL layer ELY1, the upper layer AOU1, and the sacrificial layer MWY1. Then, the material film is subjected to anisotropic etching so as to leave only the area that is in contact with the side surface of the stacked layer and remove the other areas, thus forming the side wall AOS1. The material of the side wall AOS1 is the same as that of the sacrificial layer AOM1, that is, for example, aluminum oxide (AlOx). On the other hand, the anode AD1 and the anode AD2 are formed of a metal oxide, for example, as described above.

That is, the side wall AOS1, as well as the anode AD1 and the anode AD2, are formed from a material containing a metal oxide. Here, when etching such a metal oxide, it may be necessary in some cases to use an etching gas whose selectivity ratio cannot be taken.

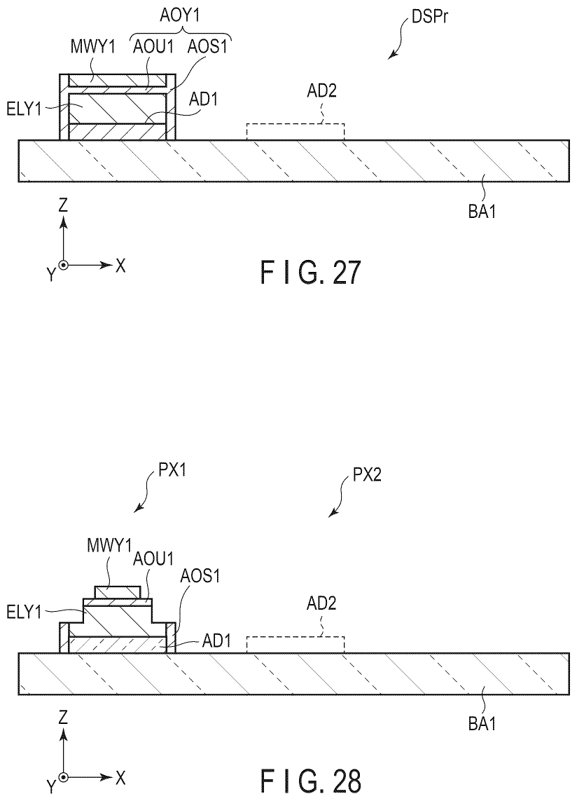

In this case, there is a risk that the anode AD2 may be removed together as well by the etching carried out to form the side wall AOS1 (see FIG. 27). If the anode is removed, the pixel does not properly emit light. In this way, the display quality will be reduced in such a display device.

FIG. 28 is a cross-sectional view showing a processing step in a method of manufacturing a display device of Comparative Example 2. As in the case of Comparative Example 1, in the manufacturing process shown in FIG. 24, anisotropic etching is carried out. At this time, there is a risk that a part of the sacrificial layer MWY1, a part of the side wall AOS1, and a part of the organic EL layer ELY1 of the pixel PX1 as well may be etched. If part of the organic EL layer ELY1 is etched, the light-emitting area of the pixel PX1 is decreased.

In this embodiment, in the stacked body subjected to anisotropic etching, a thick side wall of, for example, aluminum oxide (ALOx), is formed on a side surface of the organic EL layer ELY. Further, a layer of aluminum oxide (ALOx), for example, is formed on the upper layer of the organic EL layer ELY. With this structure, it is possible to protect the organic EL layer during anisotropic etching.

### Configuration Example 1

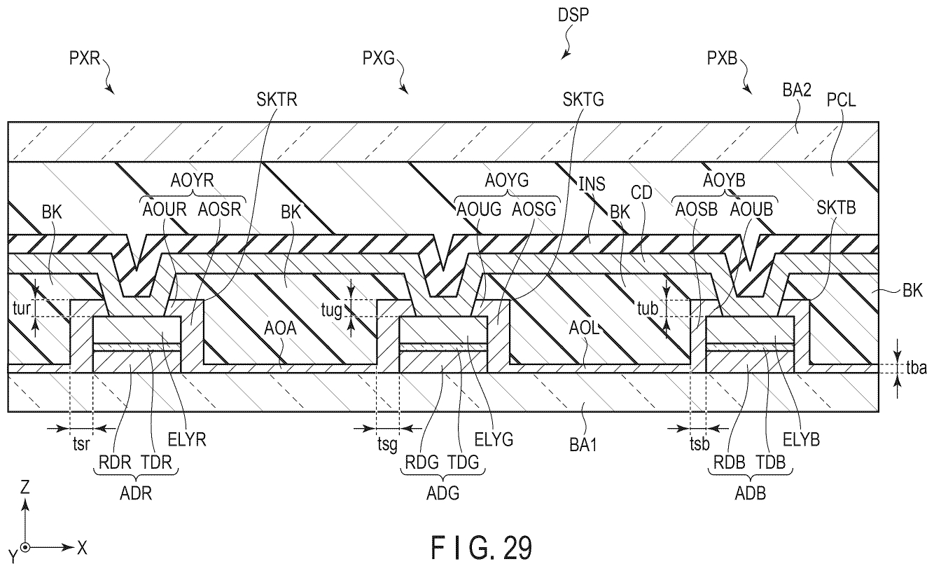

FIG. 29 is a cross-sectional view showing another configuration example of the display device in Embodiment 1. The configuration example shown in FIG. 29 is different as compared to the example shown in FIG. 4 in that the thickness tsr and the thickness tsg are the same as each other (tsr=tsg).

In the display device DSP shown in FIG. 29, the thickness of the side wall AOSR of the pixel PXR is equal to the thickness of the side wall AOSG of the pixel PXG (tsr=tsg). The thickness tsb of the side wall AOSB of the pixel PXB is less than the thickness tsr of the side wall AOSR and the thickness tsg of the side wall AOSG (tsr=tsg>tsb).

The thickness tur of the upper layer AOUR of the pixel PXR, the thickness tug of the upper layer AOUG of the pixel PXG, and the thickness tub of the upper layer AOUB of the pixel PXB are equal to each other. (tur=tug=tub).

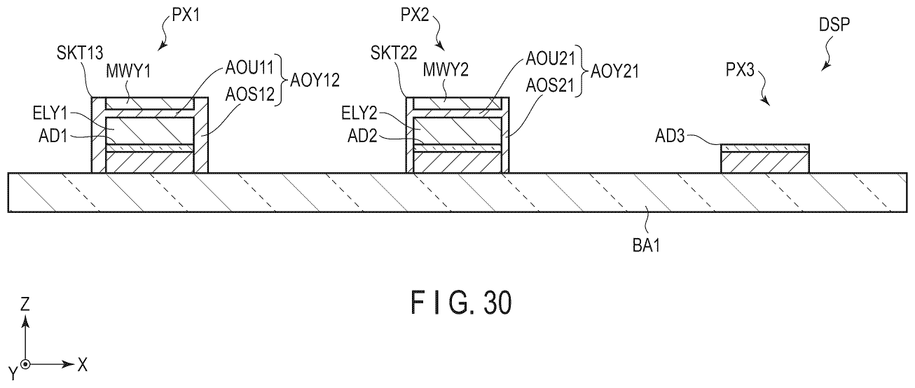

FIGS. 30 to 36 are each a cross-sectional view showing a processing step in a method of manufacturing a display device of Configuration Example 1.

As in the case of FIG. 6, an anode AD1 is formed in a pixel PX1, an anode AD2 is formed on a pixel PX2, and an anode AD3 is formed on a pixel PX3. The anode AD1 includes a reflective electrode RD1 and a transparent electrode TD1. The anode AD2 includes a reflective electrode RD2 and a transparent electrode TD2. The anode AD3 includes a reflective electrode RD3 and a transparent electrode TD3.

In the processing steps of the manufacture shown in FIGS. 6 to 17, an upper layer AOU11 and a sidewall AOS12 are formed in the pixel PX1. In the pixel PX2, an upper layer AOU21 and a side wall AOS21 are formed. In pixel PX3, an anode AD3 is formed (see FIG. 30). The cross-sectional view of the step in the manufacturing process of the display device DSP shown in FIG. 30 corresponds to that of FIG. 18.

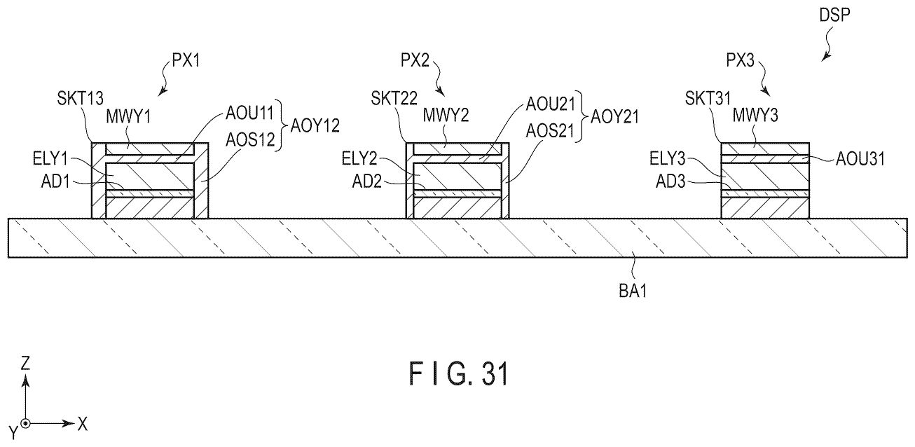

Based on the processing steps of the manufacture shown in FIGS. 13 to 15, an organic EL layer ELY3, an upper layer AOU31, and a sacrificial layer MWY3 are formed on the anode AD3 in the pixel PX3 (see FIG. 31). The anode AD3, the organic EL layer ELY3, the upper layer AOU31, and the sacrificial layer MWY3 are collectively referred to as a stacked body SKT31.

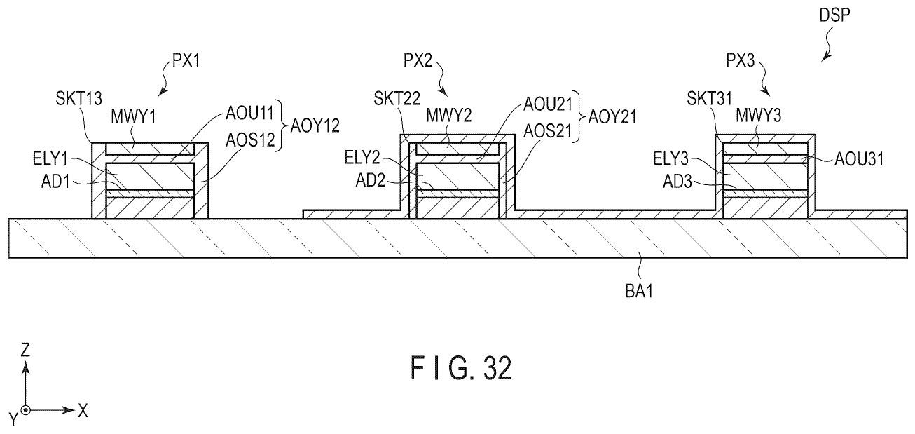

Based on the manufacturing process shown in FIG. 17, a sacrificial layer AOK3 is formed to cover the stacked body SKT22 and the stacked body SKT31. The sacrificial layer AOK3 is formed of the same material as that of the sacrificial layer AOM1. On the other hand, the sacrificial layer AOK3 is not formed in the stacked body SKT13 (see FIG. 32). Here, for example, it is sufficient to cover the stacked body SKT13 with a mask so as to avoid the sacrificial layer AOK3 from being formed.

In FIG. 32, in order to make the drawing easier to understand, the sacrificial layer AOY12 (the upper layer AOU11 and side wall AOS12) and the sacrificial layer AOK3, the sacrificial layer AOY21 (the upper layer AOU21 and side wall AOS21) and the sacrificial layer AOK3, the upper layer AOU21 and the sacrificial layer AOK3 are illustrated in separate layers, but they are integrated to ether as one body.

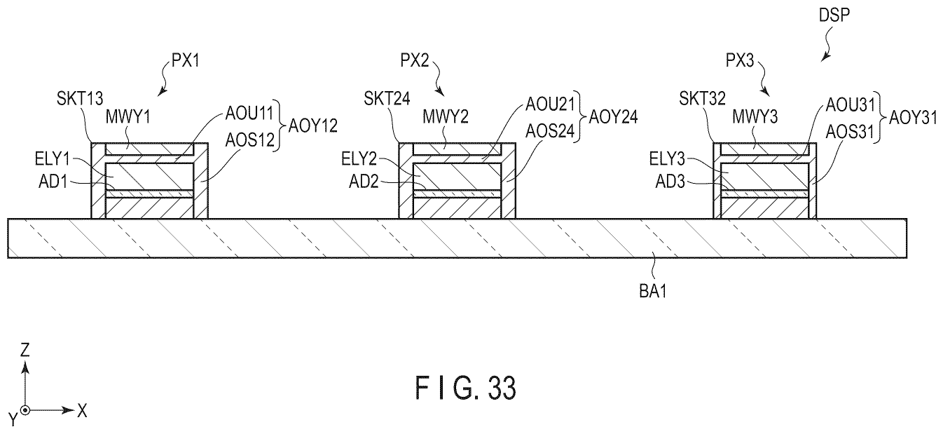

The sacrificial layer AOK3 is then subjected to anisotropic etching and thus only the area in contact with a side surface of the stacked body SKT22 and a side surface of the stacked body SKT31 is left to remain, and the other areas are removed. With this processing, a side wall AOS24 is formed from the sacrificial layer AOK3 on the side surface of the stacked body SKT22. Further, a side wall AOS31 is formed on the side surface of the stacked body SKT31 from the sacrificial layer AOK3 (see FIG. 33). As described above, the sacrificial layer AOY21 and sacrificial layer AOK3, as well as the upper layer AOU31 and sacrificial layer AOK3, are integrated with each other into one body, respectively. The side wall AOS24 is an integrated structure of the side wall AOS21 and the sacrificial layer AOK3. The upper layer AOU21 and the side wall AOS24 are integrated with each other to form the sacrificial layer AOY24. The upper layer AOU31 and the side wall AOS31 are integrated into one body and together form the sacrificial layer AOY31.

The stacked body SKT22 and the side wall AOS24 are collectively referred to as a stacked body SKT24. The stacked body SKT31 and the side wall AOS31 are collectively referred to as a stacked body SKT32.

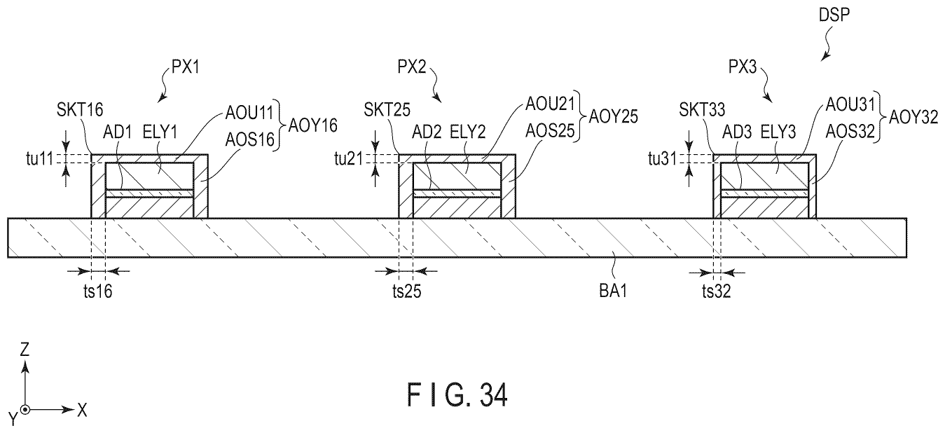

As in the case of FIG. 19, the sacrificial layer MWY1 of the stacked body SKT13, the sacrificial layer MWY2 of the stacked body SKT24, and the sacrificial layer MWY3 of the stacked body SKT32 are removed by etching. At this time, the upper portions of the side wall AOS11, side wall AOS24, and side wall AOS31 are etched at the same time. With this processing, a stacked body SKT16, a stacked body SKT25, and a stacked body SKT33 having planarized upper surfaces are obtained from the stacked body SKT13, the stacked body SKT24, and the stacked body SKT32, respectively (see FIG. 34).

The side wall AOS12, side wall AOS24, and side wall AOS31 having etched upper surfaces, are referred to as a side wall AOS16, a side wall AOS25, and a side wall AOS32, respectively. The upper layer AOU11 and the side wall AOS16 are collectively referred to as a sacrificial layer AOY16. The upper layer AOU21 and the side wall AOS25 are collectively referred to as a sacrificial layer AOY25. The upper layer AOU31 and the side wall AOS32 are collectively referred to as a sacrificial layer AOY32.

Here, the thickness of the upper layer AOU11 is defined as a thickness tu11. The thickness of the side wall AOS16 is defined as a thickness ts16. The thickness of the upper layer AOU21 is defined as a thickness tu21. The thickness of the side wall AOS25 is defined as a thickness ts25. The thickness of the upper layer AOU31 is defined as a thickness tu31. The thickness of the side wall AOS32 is defined as a thickness tS32.

The thickness tu11, thickness tu21, and thickness tu31 are the same as each other (tu11=tu21=tu31). The thickness ts16 and thickness ts25 are equal to each other. The thickness ts16 and thickness ts25 are greater than the thickness ts32 (ts16=ts25>ts32).

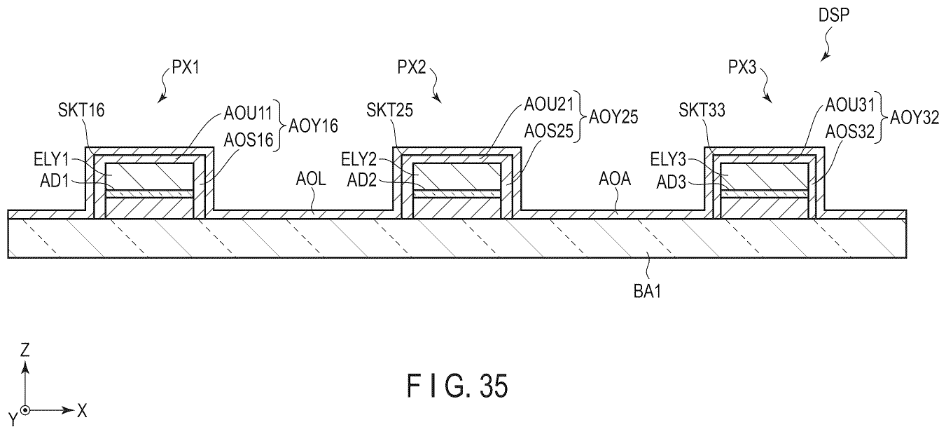

A protective layer AOL is formed to cover the stacked body SKT16, stacked body SKT25, and stacked body SKT33. The protective layer AOL is formed of the same material as that of the sacrificial layer AOM1 and the sacrificial layer AOM2 (see FIG. 35).

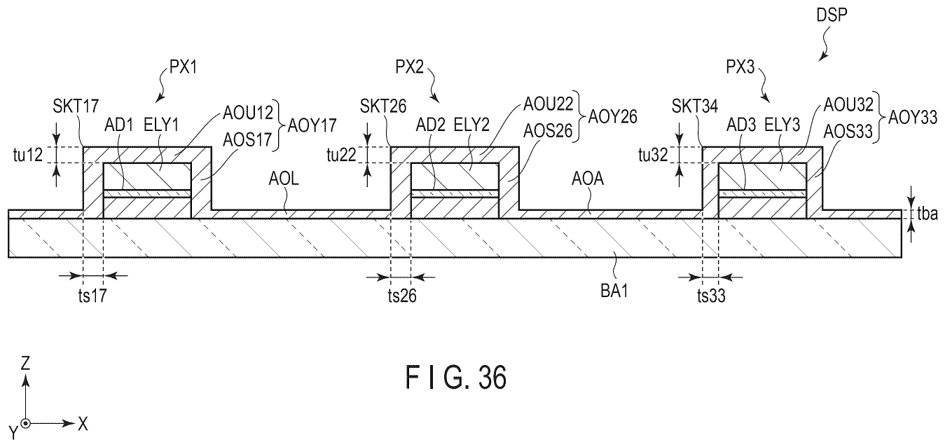

In FIG. 35, in order to make the drawing easier to understand, the sacrificial layer AOY16 (the upper layer AOU11 and side wall AOS16) and the protective layer AOL, the sacrificial layer AOY25 (the upper layer AOU21 and side wall AOS S25) and the protective layer AOL, and the sacrificial layer AOY32 (the upper layer AOU31 and side wall AOS32) and the protective layer AOL are illustrated as separate layers, but these are integrated into one body (see FIG. 36).

As shown in FIG. 36, the upper layer AOU11 and the protective layer AOL are integrated together to constitute an upper layer AOU12. The side wall AOS16 and the protective layer AOL are integrated together to constitute a side wall AOS17. The upper layer AOU12 and the side wall AOS17 are integrated together to constitute a sacrificial layer AOY17. The sacrificial layer AOY17 constitutes a part of the protective layer AOL. The stacked body SKT16 and the sacrificial layer AOY17 are collectively referred to as a stacked body SKT17.

The upper layer AOU21 and the protective layer AOL are integrated together to constitute an upper layer AOU22. The side wall AOS25 and the protective layer AOL are integrated together to constitute a side wall AOS26. The upper layer AOU22 and the side wall AOS26 are integrated together to constitute a sacrificial layer AOY26. The sacrificial layer AOY26 constitutes a part of the protective layer AOL. The stacked body SKT25 and the sacrificial layer AOY26 are collectively referred to as a stacked body SKT26.

The upper layer AOU31 and the protective layer AOL are integrated together to constitute an upper layer AOU32. The side wall AOS32 and the protective layer AOL are integrated together to constitute a side wall AOS33. The upper layer AOU32 and the side wall AOS33 are integrated together to constitute a sacrificial layer AOY33. The sacrificial layer AOY33 constitutes a part of the protective layer AOL. The stacked body SKT33 and the sacrificial layer AOY33 are collectively referred to as a stacked body SKT34.

The thickness of the upper layer AOU12 is defined as a thickness tu12. The thickness of the side wall AOS17 is defined as a thickness ts17. The thickness of the upper layer AOU22 is defined as a thickness tu22. The thickness of the side wall AOS26 is defined as a thickness ts26. The thickness of the upper layer AOU32 is defined as a thickness tu32. The thickness of the upper layer AOU33 is defined as a thickness tu33.

The thickness tu12, thickness tu22 and thickness tu32 are the same as each other (tu12=tu22=tu32). The thickness ts17 and thickness ts26 are the same as each other. The thickness ts17 and thickness ts26 are greater than the thickness ts33 (ts17=ts26>ts33).

Between each adjacent pair of the sacrificial layer AOY17, sacrificial layer AOY26, and sacrificial layer AOY34, there is an area AOA formed of the same material as that of these sacrificial layers and provided on the base BA1. The sacrificial layer AOY17, sacrificial layer AOY26, sacrificial layer AOY34, and the area AOA are formed to be integrated together to constitute the protective layer AOL.

The thickness of the area AOA is defined as a thickness tba. The thickness tba is less than the thickness tu12, thickness tu22, and thickness tu32 (tu12=tu22=tu32>tba).

The display device DSP of Configuration Example 1 is manufactured based on the processing steps shown in FIGS. 22 to 24. The pixel PX1, the pixel PX2, and the pixel PX3 may be the pixel PXR, the pixel PXG, and the pixel PXB, respectively (see FIG. 29).

The thickness tu12, thickness tu22, and thickness tu32 shown in FIG. 6 correspond to the thickness tur, thickness tug, and thickness tub shown in FIG. 30, respectively. The thicknesses ts17, thickness ts26, and thickness ts33 correspond to the thicknesses tsr, thickness tsg, and thickness tsb, respectively.

This configuration example as well exhibits advantageous effects similar to those of Embodiment 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels including a first pixel, a second pixel and a third pixel; and
a bank provided between each adjacent pair of the plurality of pixels,
each of the plurality of pixels comprising, on a base,
an anode,
an organic EL layer provided on the anode,
a protective layer provided to cover a side surface of the organic EL layer, and
a cathode provided in an aperture of the protective layer and the bank, so as to be in contact with the organic EL layer, wherein
the protective layer comprises a side wall provided on a side surface of the organic EL layer, and an upper layer provided on an upper surface of the organic EL layer,
the first pixel includes a first side wall and a first upper layer of the protective layer,
the second pixel includes a second side wall and a second upper layer of the protective layer,
the third pixel includes a third side wall and a third upper layer of the protective layer,
the first upper layer, the second upper layer, and the third upper layer have thicknesses equal to each other,
the first side wall has a thickness greater than or equal to that of the second side wall, and
the thicknesses of the first side wall and the second side wall are greater than the thickness of the third side wall.

2. The display device according to claim 1, wherein
the protective layer is formed of aluminum oxide.

3. The display device according to claim 1, wherein
the first pixel is a pixel that emits red light,
the second pixel is a pixel that emits green light, and
the third pixel is a pixel that emits blue light.

4. The display device according to claim 1, wherein
the thickness of the first side wall is greater than the thickness of the second side wall.

5. The display device according to claim 1, wherein
the thickness of the first side wall and the thickness of the second side wall are equal to each other.
